(19) United States
(12) Patent Application Publication
(10) Pub. No.: US 2025/0174435 A1
(43) Pub. Date: May 29, 2025

(54) TRANSIENT CONTROL OF AN ASYMMETRIC WAVEFORM

(71) Applicant: Advanced Energy Industries, Inc., Denver, CO (US)

(72) Inventors: Daniel Carter, Fort Collins, CO (US); Victor Brouk, Fort Collins, CO (US)

(73) Assignee: Advanced Energy Industries, Inc., Denver, CO (US)

(21) Appl. No.: 18/518,840

(22) Filed: Nov. 24, 2023

(51) Int. Cl. H01J 37/32; H03K 5/01

(52) U.S. Cl. CPC H01J 37/32155; H03K 5/01; H01J 37/32091; H01J 2237/334

(57) ABSTRACT

A bias supply comprising power circuitry configured to apply an asymmetric periodic voltage waveform at the output node wherein the asymmetric periodic voltage waveform comprises a first section that begins with a first negative voltage and changes during a first transition to a peak voltage before changing during a second transition to a second negative voltage and a second section that begins with the second negative voltage and comprises a voltage ramp between the second negative voltage and a third negative voltage. Transition circuitry is configured to adjust a slope of one, or both, of the first and second transitions.

### BACKGROUND

### Field of the Disclosure

The present disclosure relates generally to power supplies. More specifically, but without limitation, the present disclosure relates to controlling an application of an asymmetric waveform.

### Background

Many types of semiconductor devices are fabricated using plasma-based etching techniques. If it is a conductor that is etched, a negative voltage with respect to ground may be applied to the conductive substrate to create a substantially uniform negative voltage across the surface of the substrate conductor, which attracts positively charged ions toward the conductor, and as a consequence, the positive ions that impact the conductor have substantially the same energy.

If the substrate is a dielectric, however, a non-varying voltage is ineffective to place a voltage across the surface of the substrate. But an alternating current (AC) voltage (e.g., high frequency AC or time varying periodic voltage waveform may be applied by a bias supply to the conductive plate (or chuck) so that the AC field induces a voltage on the surface of the substrate. During a negative portion of the applied waveform, the surface of the substrate will be charged negatively, which causes ions to be attracted toward the negatively-charged surface during the negative portion of the periodic cycle. And when the ions impact the surface of the substrate, the impact dislodges material from the surface of the substrate—effectuating the etching.

During operation of a bias supply, the bias supply undergoes state changes, and the periodic waveform may by changed, consistent with state changes, to effectuate different ion energy distribution functions (IEDFs). For example, directionality, feature profile, and selectivity to a mask and a stop-layer may be controlled by making state changes to the bias supply to adjust the IEDF.

In some circumstances, a particular distribution of ion energies (or IEDF) may be desired, which may require accurate control of the sheath voltage (Vₛₕₑₐₜₕ), which generally refers to the potential difference (or voltage drop) from the plasma to the substrate surface. A bias power system may be utilized to control the voltage drop across the sheath in plasma processing systems in order to control the distribution of ion energies to a substrate.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

Some aspects may be characterized as a bias supply comprising an output node and power circuitry configured to apply an asymmetric periodic voltage waveform at the output node wherein the asymmetric periodic voltage waveform comprises a first section that begins with a first negative voltage and changes during a first transition to a peak voltage before changing during a second transition to a second negative voltage. And the asymmetric periodic voltage waveform comprises a second section that begins with the second negative voltage and comprises a voltage ramp between the second negative voltage and a third negative voltage. Transition circuitry is configured to adjust a slope of one, or both, of the first and second transitions.

Other aspects may be characterized as a method comprising applying a first section of an asymmetric periodic voltage waveform to a plasma processing chamber where the first section begins with a first negative voltage and changes during a first transition to a second peak voltage before changing during a second transition to a second negative voltage. The method also includes applying a second section of the asymmetric periodic voltage waveform that begins with the second negative voltage and comprises a voltage ramp between the second negative voltage and a third negative voltage. And a slope of one, or both, of the first and second transitions is adjusted.

Yet other aspects relate to a non-transient computer-readable storage medium having instructions embodied thereon, the instructions are executable by a processor and/or capable of programming a field programmable gate array, the instructions including instructions for applying a first section of an asymmetric periodic voltage waveform to a plasma processing chamber, the first section begins with a first negative voltage and changes during a first transition to a second, peak voltage before changing during a second transition to a second negative voltage. The instructions also include instructions for applying a second section of the asymmetric periodic voltage waveform that begins with the second negative voltage and comprises a voltage ramp between the second negative voltage and a third negative voltage. And the instructions include instructions for adjusting a slope of one, or both, of the first and second transitions.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

FIG. 1 is a block diagram depicting an exemplary plasma processing environment utilizing one or more bias supplies, according to various aspects of the disclosure.

FIG. 2 is a graph depicting aspects of an asymmetric periodic waveform.

FIG. 3 is a block diagram depicting aspects of a bias supply.

FIG. 4 is a flowchart depicting a method that may be traversed in connection with embodiments disclosed herein.

FIG. 5 is a graph depicting conceptual aspects of an asymmetric periodic voltage waveform resulting from the method depicted in FIG. 4.

FIG. 6 is a graph depicting actual measurements of an asymmetric periodic voltage waveform resulting from the method depicted in FIG. 4.

FIG. 7 is a graph depicting the spectral content of an asymmetric periodic voltage waveform that results from the method depicted in FIG. 4.

FIG. 8 is a graph depicting the effect of the method depicted in FIG. 4 on compensation current.

FIG. 9 illustrates an example topology of a bias supply that comprises two power supplies and two active switches.

FIG. 10 illustrates another example topology of a bias supply that comprises two power supplies and two active switches.

FIG. 11 illustrates yet another example topology of a bias supply that comprises two power supplies and two active switches.

FIG. 12 illustrates an example topology of a bias supply that comprises two power supplies and one active switch.

FIG. 13 illustrates another example topology of a bias supply that comprises one power supply and two active switches.

FIG. 14 illustrates yet another topology of a bias supply that comprises one power supply and one active switch.

FIG. 15A is an example of a variable reactance comprising a variable inductance.

FIG. 15B is an example of a variable reactance comprising a variable inductance and a fixed capacitance.

FIG. 15C is an example of a variable reactance comprising a variable inductance and a variable capacitance.

FIG. 15D is an example of a variable reactance comprising a fixed inductance and a variable capacitance.

FIG. 15A is an example of a variable reactance comprising a variable inductance.

FIG. 16 illustrates a block diagram depicting components that may be utilized to implement control aspects disclosed herein, according to various aspects of the disclosure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments. In this regard, some blocks in these flowcharts or block diagrams may represent a module, segment, or portion of code, which comprises one or more executable instructions for implementing the specified logical function(s). The instructions may be executable by a processor or may be used to program a field programmable gate array. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, “source generators” or “excitation supplies” are those whose energy is primarily directed to generating and sustaining the plasma, while “bias supplies” are those whose energy is primarily directed to generating a surface potential for attracting ions and electrons from the plasma. As used herein, the terms “workpiece”, “substrate”, or “wafer” may be used interchangeably throughout the disclosure.

As discussed above, bias supplies may be used to apply an asymmetric periodic voltage function (also referred as an asymmetric periodic voltage waveform) to a substrate support in a plasma processing chamber.

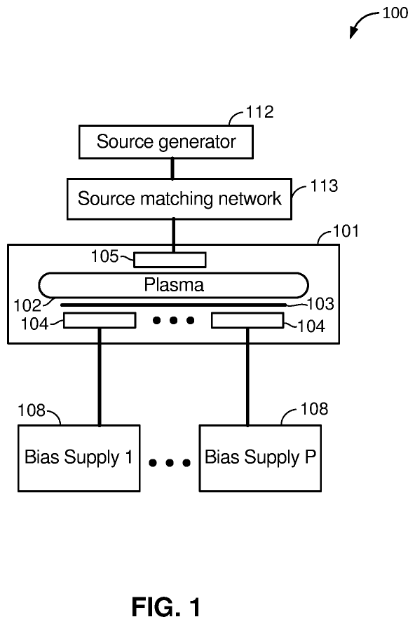

Referring first to FIG. 1, shown is an exemplary plasma processing environment 100, such as a deposition or etch system, in which one or more bias supplies may be utilized. The plasma processing environment 100 may include many pieces of equipment coupled directly and indirectly to a plasma processing chamber 101, within which a volume containing a plasma 102 and workpiece 103 (e.g., a wafer or substrate) and electrodes 104 (which may be embedded in a substrate support) are contained. The equipment may include vacuum handling and gas delivery equipment (not shown), one or more bias supplies 108, one or more source generators 112, and one or more source matching networks 113. In many applications, power from a single source generator 112 is connected to one or multiple source electrodes 105. The source generator 112 may be a higher frequency RF generator (e.g., 13.56 MHz to 120 MHz). The electrode 105 generically represents what may be implemented with an inductively coupled plasma (ICP) source, a dual capacitively-coupled plasma source (CCP) having a secondary top electrode biased at another RF frequency, a helicon plasma source, a microwave plasma source, a magnetron, or some other independently operated source of plasma energy. Although not shown in FIG. 1, it should also be recognized that a bias supply 108 may also be coupled to the electrode 105 in a CCP configuration where combined source and bias energy is directed to a single electrode.

In variations of the system depicted in FIG. 1, the source generator 112 and source matching network 113 may be replaced by, or augmented with, a remote plasma source. And other variations of the system may include only a single bias supply 108. It should be recognized that many other variations of the plasma processing environment depicted in FIG. 1 may be utilized. As examples without limitation, U.S. Pat. No. 10,707,055, issued Jul. 7, 2020, and U.S. Pat. No. 10,811,227, issued Oct. 20, 2020, both of which are incorporated by reference in their entirety, disclose various types of system designs.

It should also be recognized that, while the following disclosure generally refers to plasma-based workpiece processing, implementations can include any substrate processing within a plasma chamber. In some instances, objects other than a substrate can be processed using the systems, methods, and apparatus herein disclosed. In other words, this disclosure applies to plasma processing of any object within a sub-atmospheric plasma processing chamber to make a surface change, subsurface change, deposition or removal by physical or chemical means.

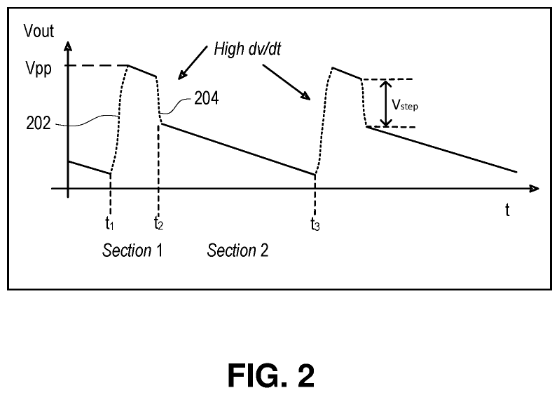

FIG. 2, shown is an asymmetric periodic voltage waveform that can be generated by the bias supplies of the present disclosure. As shown in FIG. 2, each cycle of the asymmetric periodic voltage waveform comprises the first section (Section 1) that begins with a first negative voltage (at t1) and changes to a positive peak voltage, Vpp, during the first section. Further, at or near the end of the first section, the asymmetric periodic voltage drops to a second negative voltage (at t2), which is a beginning of Section 2. During Section 2, the asymmetric periodic voltage waveform comprises a voltage ramp (also referred to as a negative voltage ramp) between the second negative voltage and a third negative voltage (at t3), which may, or may not be, the same voltage as the first negative voltage. Although the voltage ramp may be linear, it should be recognized that the voltage ramp may also be nonlinear. Depending upon a desired processing result, the first negative voltage may be the same as, or may be different than, the third negative voltage over several cycles of the asymmetric periodic voltage waveform.

In many modes of operation, the asymmetric periodic voltage waveform is applied at a relatively low frequency (relative to a source generator). For example and without limitation, the asymmetric periodic voltage waveform may be applied at 400 kHz in contrast to the higher frequencies (e.g., 13.56 MHz to 120 MHz) applied by a source generator. One goal of utilizing a low frequency, asymmetric periodic voltage waveform is to separate plasma formation from ion energy generation. For example, independent control of ion density by plasma formation (with a source generator) and ion energy (with a bias supply) is often desirable. But features of the asymmetric waveform may contribute to plasma formation. For example, the slope of the voltage transitions at t1 and t2 in and out of a voltage reversal portion (between times t1 and t2) are known to contribute to plasma generation, which may be due, at least in part, to a high-frequency content of the waveform. Applicant has found that, by decreasing the rate of rise and/or fall in the voltage during these transitions at t1 and t2, the high frequency content may be decreased to reduce plasma generation in these portions of the waveform.

Although the fundamental frequency of the asymmetric periodic voltage function may be 400 kHz, the sharp transitions occurring at the beginning (at t1) and end (at t2) of the voltage reversal section may produce spectral features occurring at much higher frequencies. These harmonics, even at low amplitude, have the potential to ionize gas with relative efficiency, and as a consequence, cause increased contribution to plasma formation. Applicant has also found that increasing the bias magnitude results in higher compensation current needed to produce a narrow ion energy distribution function (IEDF), and increasing the bias magnitude also contributes to higher plasma density.

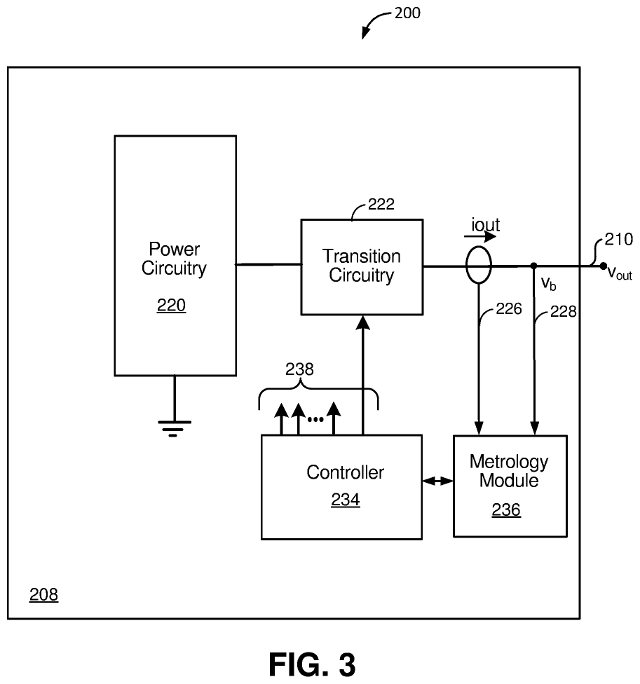

Referring to FIG. 3, shown is a biasing system 200 comprising an exemplary bias supply 208 that may be utilized to implement the bias supplies 108 described with reference to FIG. 1. The bias supply 208 generally represents many variations of bias supplies described further herein to apply an asymmetric periodic voltage function. Thus, reference to the bias supply 208 generally refers to any of the bias supplies described further herein. As shown, the bias supply 208 includes an output node 210 (also referred to as an output 210), power circuitry 220, transition circuitry 222, a metrology module 236, and a controller 234. In general, the bias supply 208 functions to apply an asymmetric periodic voltage function at the output node 210. As one of ordinary skill in the art will appreciate, output current, iₒᵤₜ, delivered to a load through the output node 210 may optionally be returned to the bias supply 208 through a return node that may be common with the load.

FIG. 2 also depicts examples of electrical parameters that are associated with the bias supply 208. For example, output current, iₒᵤₜ, may be measured along a current path, as shown, between the power circuitry 220 and the output node 210. In addition, the output voltage, vₒᵤₜ, is another electrical parameter that may be measured and utilized as described herein. For example, vₒᵤₜ may be the voltage (or potential difference) between the output node 210 and a return node (not shown), or as another example, vₒᵤₜ, may be the voltage (or potential difference) between the output node 210 and ground (shown as a ground symbol).

As shown, the bias supply 208 may include a controller 234 that functions to control the power circuitry 220 and transition circuitry 222 based upon one or more of the electrical parameters (e.g., iₒᵤₜ, and vₒᵤₜ, to name examples without limitation). The controller 234 may reside within a housing of the bias supply 208, or alternatively, may reside external to the housing of the bias supply 208. When implemented external to the housing of the bias supply 208, the controller 234 may be implemented as a portion of a centralized controller that controls several pieces of processing equipment such as, for example and without limitation, the bias supply 208, the source generator (e.g., shown as source generator 112 in FIG. 1), the source matching network 113, other bias supplies (e.g., shown as bias supplies 108 in FIG. 1), mass flow controllers, and other applicable components. The controller 234 may also be distributed between the bias supply 208 and control-related components that are external to the bias supply 208. It is also contemplated that the controller 234 may be implemented within a housing of another piece of equipment such as the source generator, such as source generator 112 in FIG. 1, or the controller 234 may be implemented as a distributed controller that resides in several pieces of equipment.

As shown, the controller 234 is in communication with the metrology module 236. The depiction of the metrology module 236 is logical for purposes of describing functional aspects of the controller 234 and the metrology module 236, but is should be recognized that the controller 234 and the metrology module 236 may be realized by common underlying hardware and/or software/firmware constructs. For example, the controller 234 and the metrology module 236 may share one or more common processors and/or field programmable gate arrays (FPGAs). As one of ordinary skill in the art will appreciate, dedicated hardware constructs, processor executable instructions and/or instructions to program an FPGA may be utilized to effectuate control methods described further herein.

As shown, the metrology module 236 may receive one or more signals including a current signal 226 indicative of the output current, iₒᵤₜ, and voltage signals 228 indicative of the output voltage, vₒᵤₜ. Although not shown in FIG. 3 for purposes of simplicity, those of ordinary skill in the art will readily appreciate that the output current, iₒᵤₜ and output voltage, vₒᵤₜ may be sensed by current and voltage sensors readily known in the art to produce the current signal 226 and voltage signal 228, and the current signal 226 and voltage signal 228 may be may be sampled and converted to produce digital representations of the current signal 226 and voltage signal 228. In some cases, these measurements are utilized as a means of feedback to the controller 234, and the controller 234 may adjust the output parameters (e.g., iₒᵤₜ, vₒᵤₜ) of the bias supply 208 based upon the feedback.

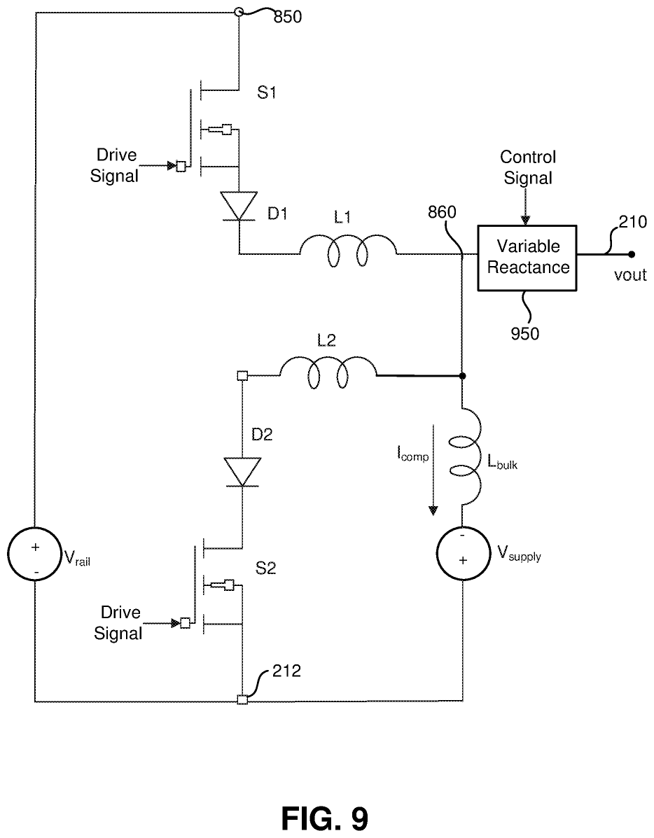

For example, the controller 234 is configured to control (by providing control signals 238) the power circuitry 220 and the transition circuitry 222 to effectuate desired aspects of the asymmetric periodic voltage waveform that is applied to the output node 210. It is also contemplated that the extracted information about the plasma characteristics (provided by the metrology module 236) may be used to control the source generator 112 and/or the matching network 113. Variations of the power circuitry 220 and transition circuitry 222 are disclosed further herein in relation to FIGS. 9-15D. Several examples of power circuitry 220 are provided further herein, but these are only examples and it is contemplated that other topologies may be used to generate the asymmetrical periodic voltage waveforms disclosed herein. The transition circuitry generally functions to enable control over the first transition 202 and the second transition 204 and a variety of different electrical circuits may be utilized to realize the transition circuitry 222 including the controllable variable reactances disclosed herein.

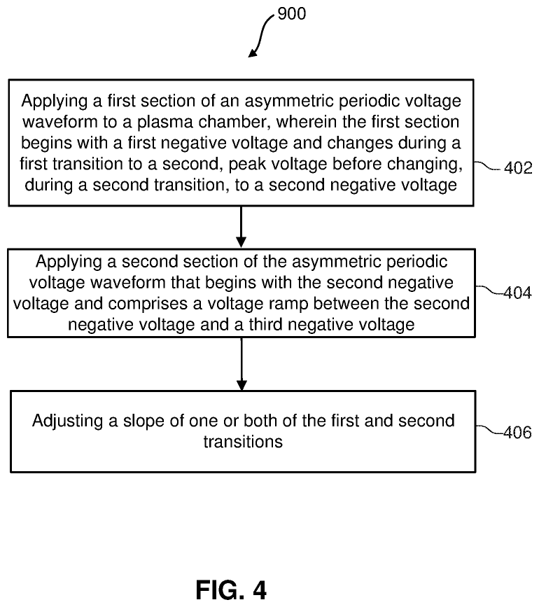

While referring to FIGS. 2 and 3, simultaneous reference is made to FIG. 4, which is a flow chart depicting a method that may be traversed in connection with the embodiments disclosed herein. As shown in FIG. 4, the power circuitry 220 applies a first section of an asymmetric periodic voltage waveform (such as the asymmetric periodic voltage waveform shown in FIG. 2) to a plasma processing chamber (e.g., to one of the electrodes 104), the first section begins with a first negative voltage (at t1) and changes during a first transition 202 to a second, peak voltage, Vpp, before changing during a second transition 204 to a second negative voltage (at t2) (Block 402). The power circuitry 220 also applies a second section of the asymmetric periodic voltage waveform that begins with the second negative voltage (at t2) and comprises a voltage ramp between the second negative voltage and a third negative voltage (at t3) (Block 404), and the transition circuitry 222 adjusts the first transition 202 and/or the second transition 204 (Block 406).

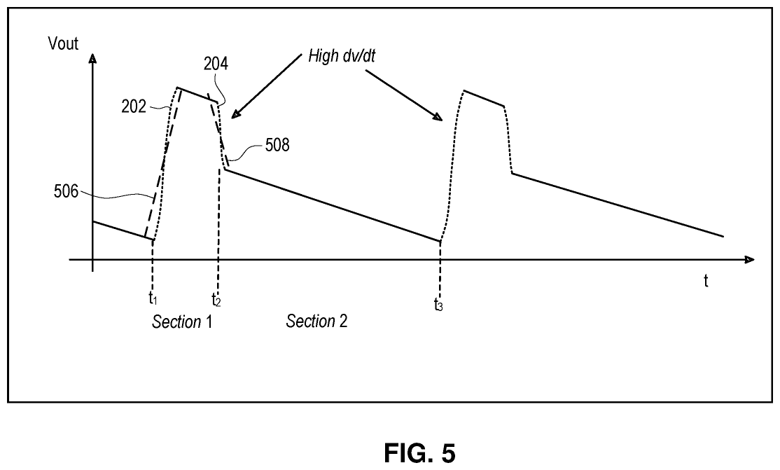

In many modes of operation, slope (also referred to as dv/dt) of first transition 202 and/or the second transition 204 are adjusted to achieve a desired slope for each of the transitions (Block 406). Shown in FIG. 5, for example, are an adjusted first transition 506 and an adjusted second transition 508. In the example of FIG. 5, the adjustment to the first transition 202 produced the adjusted first transition 506 and the adjustment to the second transition 204 produced the adjusted second transition 508. As shown, the adjustment at Block 406 may include adjusting a slope of the first transition 202 and/or the second transition 204. Reducing the slope of the first transition 202 and/or the second transition 204 reduces harmonic content, and as a consequence, reduces contributions the first transition 202 and/or the second transition 204 have on plasma density formation.

One of ordinary skill in the art appreciates, in view of this disclosure, that adjusting the slope of the first transition 202 and/or the second transition 204 may include a consideration of an amount of etching desired per unit of time. More specifically, Section 2 of the asymmetric periodic voltage waveform is generally the time frame where etching occurs because the negative voltage of the asymmetric periodic voltage waveform attracts positive ions in the plasma processing chamber 101 to the workpiece 103. But increasing the slope of the first transition 202 and/or the second transition 204 may decrease a length of Section 2. So, adjusting the slope of the first transition 202 and/or the second transition 204 (at Block 406) may include reducing the slope of the first transition 202 and/or the second transition 204 until a threshold length of Section 2 is achieved. For example, the threshold may be a minimum time length for Section 2 so that a minimum duty cycle is maintained while mitigating against high frequency harmonics.

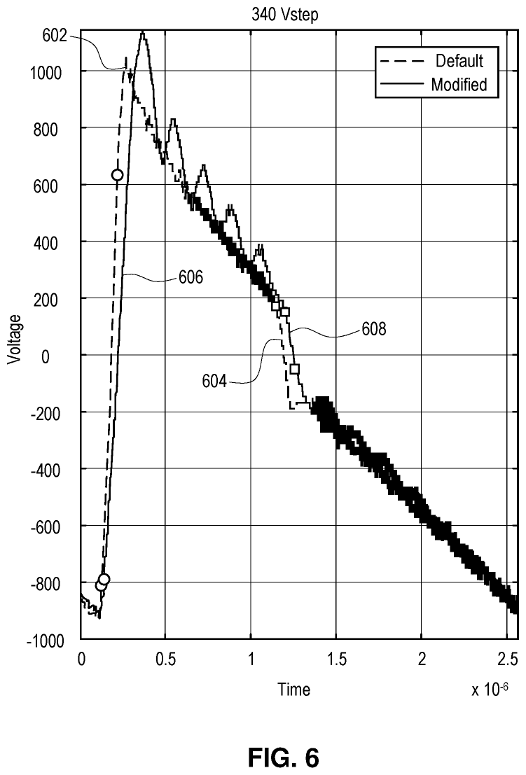

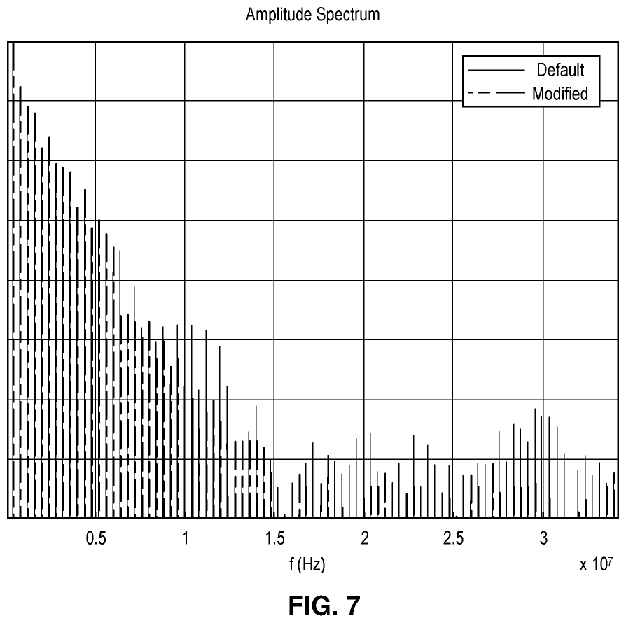

Referring next to FIG. 6, shown is another example of adjustments made to a default asymmetric periodic voltage waveform with a default first transition 602 and a default second transition 604 to produce a modified asymmetric periodic voltage waveform with an adjusted first transition 606 and an adjusted second transition 608. And FIG. 7 depicts the spectral content of the default asymmetric periodic voltage waveform and the modified asymmetric periodic voltage waveform. As shown, the slope of the adjusted first transition 606 and the slope of the adjusted second transition 608 have been reduced relative to the respective default first transition 602 and a default second transition 604, which results in the modified asymmetric periodic voltage waveform having substantially less spectral content above 15 MHz. The reduced content at high frequency harmonics results in the asymmetric periodic voltage waveform contributing less to the formation of plasma in the plasma processing chamber 101. In addition, as discussed further herein, the reduction in high-frequency harmonics means less compensation current is required (during Section 2 of the asymmetric periodic voltage waveform) to achieve a desired distribution of ion energies.

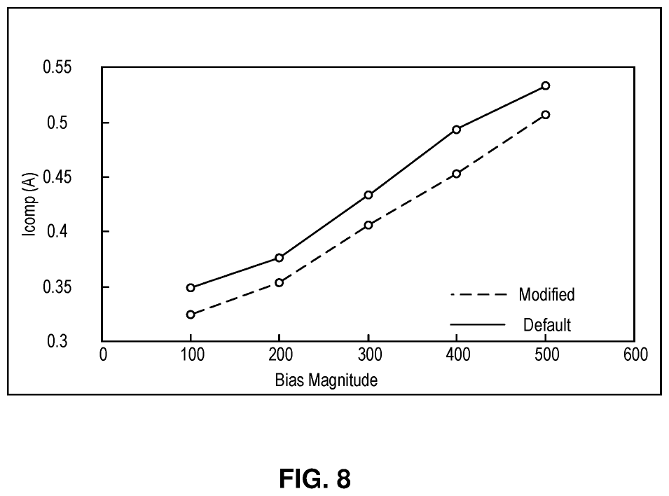

Referring to FIG. 8 for example, shown are graphs of ion compensation current, Icomp, versus bias magnitude that is required to maintain a sheath voltage (during Section 2 of the asymmetric periodic voltage waveform) for a bias supply. As shown, across a range of bias magnitudes, the amount of compensation current needed to achieve a narrow ion energy distribution is lower. Those of ordinary skill in the art of power supplies used for biasing substrates in the context of plasma processing are very aware of the need for compensation current to be applied by a bias supply (to compensate for positive-ion current in the plasma processing chamber 101) in order to achieve a desired (e.g., narrow) distribution of ion energies, and as a consequence, further details about the desirability are not provided herein, but U.S. Pat. No. 11,670,487 entitled Bias Supply Control and Data Processing, issued Jun. 6, 2023, is incorporated herein by reference for its disclosure of several techniques for compensating for ion current.

The transition circuitry 222 depicted in FIG. 3 may be realized by a variable reactance. For example, the variable reactance may be controllable to adjust the reactance presented to the bias supply 208 to enable the first transition 202 and/or the second transition 204 to be controllably modified. The variable reactance may be implemented in connection with a variety of different types of topologies for the power circuitry 220.

Referring to FIG. 9, shown is an example topology for the power circuitry 220 of the bias supply 208, comprising a switch network that comprises at least two switches, according to various aspects of the disclosure. In this example, the bias supply comprises two switches, S1 and S2, and two power supplies: a first power supply, Vrail, and a second power supply, Vsupply. The switch network is a two-switch network that couples to Vrail at node 850, the return node 212, and the output node 210.

As depicted, the switch network comprises a first switch, S1, arranged in series with a first diode D1 and a first inductor L1 between node 850 and node 860. A cathode of the diode D1 is coupled to the first inductor L1 and an anode of the diode D1 is coupled to the switch S1. That is, the switch, S1, is positioned between the positive node of Vᵣₐᵢₗ and a diode, D1. The switch network also comprises a second switch S2 (arranged in series with a second diode D2 and a second inductor L2) between the return node 212 and node 860. An anode of the diode D2 is coupled to the second inductor L2 and a cathode of the diode D2 is coupled to the switch S2. In addition, a variable reactance 950 is positioned between the node 860 and the output node 210. Here, L_{bulk} represents an inductance of the bias supply and is positioned between the node 860 and the negative node of V_{supply}, while the positive node of V_{supply} is coupled to the return node 212. FIG. 9 also depicts the compensation current, I_{comp}, flowing through the bulk inductance, L_{bulk}. The compensation current, I_{comp}, is a controllable DC current that can be controlled by the user to produce the desired output, vₒᵤₜ, and/or substrate voltage, v_{sub}, profile. In some cases, the compensation current, I_{comp}, may be controlled in conjunction with the step voltage, vₛₜₑₚ. In some embodiments, a gate drive signal is applied to the switches, S1 and S2, where the gate drive signal is provided via a gate drive signal generator, such as the gate drive signal generator known in the art. U.S. Pat. No. 11,670,487 entitled Bias Supply Control and Data Processing, issued Jun. 6, 2023, is incorporated herein by reference for its disclosure of several techniques for controlling Icomp and Vstep in connection with a variety of different topologies.

In operation, first diode D1 conducts when the first switch S1 is closed, and the second diode D2 conducts when the second switch D2 is closed. The first switch S1 and the second switch S2 are controlled to produce the asymmetric periodic voltage waveform Vₒᵤₜ and the output current iₒᵤₜ. Although not depicted, it should be recognized that the position of the first switch S1 and the position of the first diode D1 may be swapped. Similarly, the position of the second switch S2 and the position of the second diode D2 may be swapped.

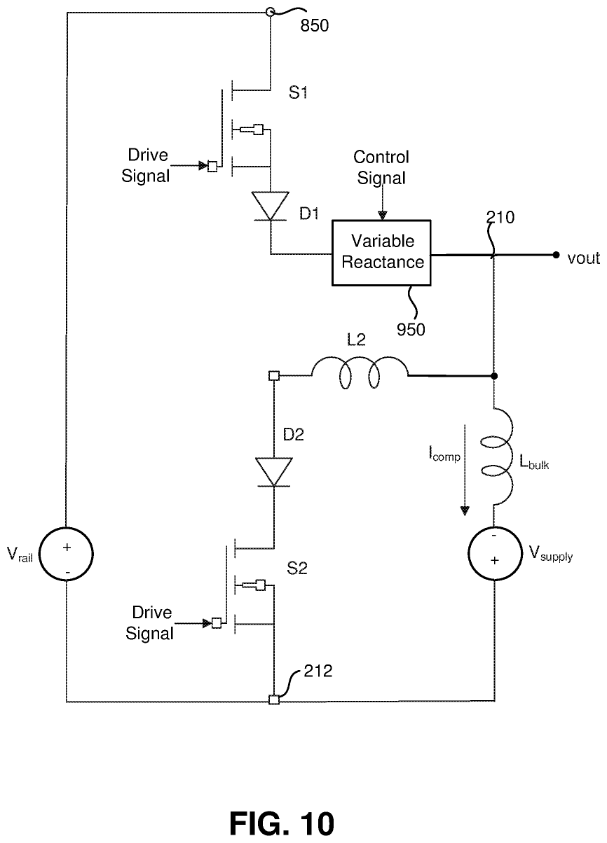

Referring to FIG. 10, shown is another example topology for the power circuitry 220 of the bias supply 208. The topology depicted in FIG. 10 is similar to the topology in FIG. 9 except that the variable reactance 950 is moved to replace the first inductor L1. In operation, first diode D1 conducts when the first switch S1 is closed, and a second diode D2 conducts when the second switch D2 is closed. And the first switch S1 and the second switch S2 are controlled to produce the asymmetric periodic voltage waveform Vout and the output current iout. Although not depicted, it should be recognized that the position of the first switch S1 and the position of the variable reactance 950 may be swapped. Similarly, the position of the second switch S2 and the position of the second diode D2 may be swapped.

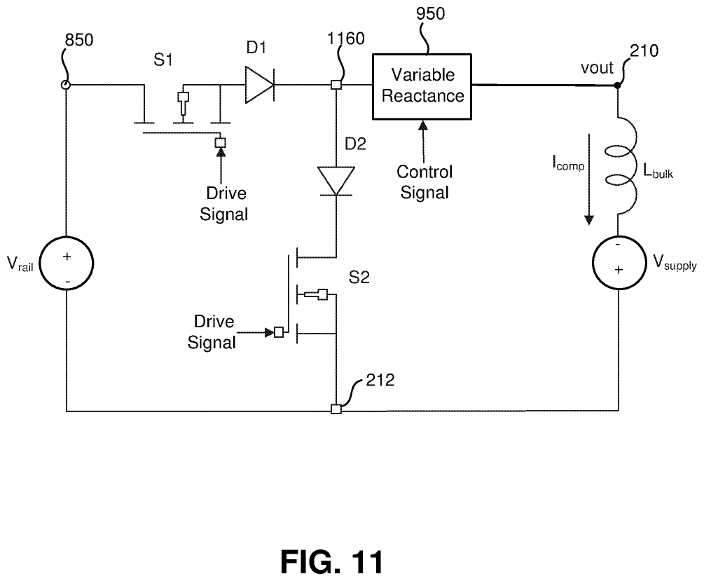

Referring to FIG. 11, shown is another example topology of the bias supply 208, comprising power circuitry that comprises a switch network with two active switches, according to various aspects of the disclosure. In this example, the bias supply comprises two switches, S1 and S2, and two power supplies: a first power supply, Vrail, and a second power supply, Vsupply. The switch network is a two-switch network that couples to Vrail at node 850, the return node 212, and the output node 210. Also shown for reference in the switch network is node 860.

As depicted, the switch network comprises a first switch, S1, arranged in series with a first diode D1 between node 850 and node 1160. A cathode of the diode D1 is coupled to the node 1160 and an anode of the diode D1 is coupled to the switch S1. That is, the switch, S1, is positioned between the positive node of Vrail and a diode, D1. The switch network also comprises a second switch S2 (arranged in series with a second diode D2) between the return node 212 and node 1160. An anode of the diode D2 is coupled to the node 1160 and a cathode of the diode D2 is coupled to the switch S2. In addition, in this variation, the variable reactance 950 is positioned between the node 1160 and the output node 210. In other words, the cathode of diode D1, the anode of diode D2, and one end of the inductor L1 is coupled to the node 1160, while the opposing end of the variable reactance 950 is coupled to the output node 210. Here, Lbulk represents an inductance of the bias supply and is positioned between the output node 210 and the negative node of Vsupply, while the positive node of Vsupply is coupled to the return node 212. FIG. 11 also depicts the compensation current, Icomp, flowing through the plasma bulk inductance, Lbulk. The compensation current, Icomp, is a controllable DC current that can be controlled by the user to produce the desired output, vout, and/or substrate voltage, vsub, profile. In some cases, the compensation current, Icomp, may be controlled in conjunction with the step voltage, vstep. In some embodiments, a gate drive signal is applied to the switches, S1 and S2, where the gate drive signal is provided via a gate drive signal generator known in the art. Beneficially, reducing high-frequency harmonics of the asymmetrical voltage waveform (by reducing a slope of first transition 202 and/or second transition 204) enables a level of compensation current, Icomp, to be reduced to achieve a narrow distribution of ion energies.

In operation, first diode D1 conducts when the first switch S1 is closed, and a second diode D2 conducts when the second switch D2 is closed. And the first switch S1 and the second switch S2 are controlled to produce the asymmetric periodic voltage waveform Vout and the output current iout. Although not depicted, it should be recognized that the position of the first switch S1 and the position of the first diode D1 may be swapped. Similarly, the position of the second switch S2 and the position of the second diode D2 may be swapped.

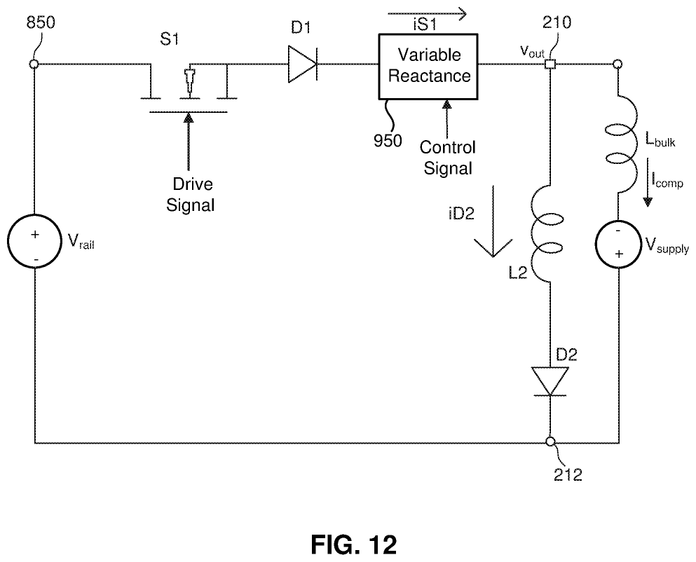

FIG. 12 illustrates a second example topology of the bias supply 208, comprising power circuitry 220 comprising two power supplies, Vrail and Vsupply, and a switch network having one active switch, S1, according to various aspects of the disclosure. It should be recognized that the active switch, S1, may comprise several switches arranged in series and/or may comprise several switches arranged in parallel. Thus, switch, S1, generally represents one or more switching components that function as a single switch to provide a single-switched current path between node 212 and node 850.

As shown, the switch network comprises a first current pathway (for current iS1), between the node 850 and the output node 210. The first current pathway comprises a series combination of the switch S1, a diode D1, and the variable reactance 950. In addition, the switch network comprises second current pathway for current iD2 between the output node 210 and the return node 212, where the second current pathway comprises a second diode D2 and an inductive element, L2, arranged in series.

In operation, the switch S1 in switch network may be operated to create the asymmetric periodic waveform Vout and the output current iout. It should be recognized that because the switch S1, the diode D1, and the variable reactance 950 are arranged in series, the order in which the switch S1, the diode D1, and the variable reactance 950 are positioned between node 850 and the output node 210 may be swapped.

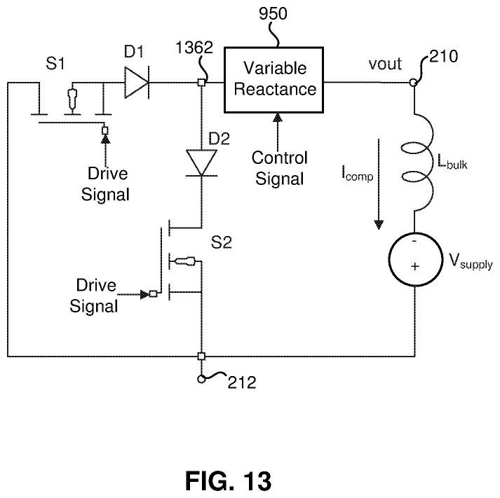

FIG. 13 illustrates another topology for the power circuitry 220 of the bias supply 208, comprising a single power supply, Vsupply, and a switch network comprising two active switches, S1 and S2, according to various aspects of the disclosure. The bias supply in FIG. 13 implements one or more aspects of the bias supplies described in relation to the figures below.

In the variation depicted in FIG. 13, a series combination of the first switch S1 and the first diode D1 is arranged between the return node 212 of the bias supply and node 1362. In addition, a series combination of the second switch S2 and the second diode D2 is arranged between the node 1362 and the return node 212 of the bias supply. As shown in FIG. 13, the first diode D1 is arranged between the first switch S1 and the node 1362 with its anode coupled to the first switch S1 and its cathode coupled to the node 1362. The second diode D2 is arranged between the second switch S2 and the node 1362 with its cathode coupled to the second switch S2 and its anode coupled to the node 1362. In this arrangement, the cathode of the first diode D1, the anode of the second diode D2, and one end of the variable reactance 950 are coupled at the node 1362, while the opposing end of the variable reactance 950 is coupled to the output node 210.

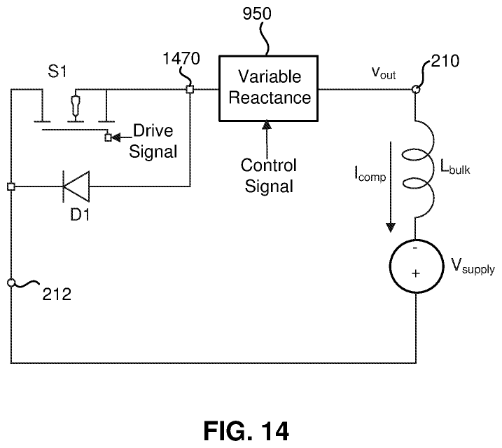

FIG. 14 illustrates yet another example topology that may be used to realize the power circuitry 220 of the bias supply 208 comprising a single power supply, Vsupply, and a switch network having a single active switch, S1, according to various aspects of the disclosure.

In the switch network shown in FIG. 14, variable reactance 950 is coupled between a node 1470 and the output node 210, and the switch S1 is coupled between the node 1470 and the return node 212. A diode D1 is coupled in parallel with the switch S1 between the node 1470 and the return node 212. In operation, the switch S1 is opened and closed to produce the asymmetric periodic voltage function Vout and the output current iout. For example, an application of the asymmetric periodic voltage waveform is effectuated between the output node 210 and the return node 212 by closing the switch S1 to cause the output current iout to change from −Io to a peak value and back to −Io. After the switch S1 is opened, the current increases to a peak value in an opposite direction and back to −Io.

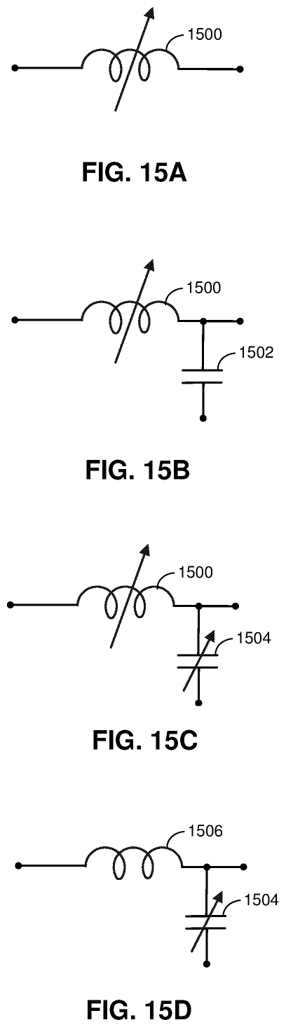

Referring next to FIGS. 15A-15D, shown are examples of the variable reactance 950, which may be utilized to realize the transition circuitry 222. In general, the variable reactance may include a combination of fixed and variable reactive elements. As shown in FIG. 15A, the variable reactance 950 may include a variable inductance 1500 that is adjustable by way of one or more control signals 238 from the controller 234. The variable reactance 950 may also include the variable inductance 1500 in connection with a fixed capacitance 1502 as shown in FIG. 15B. Alternatively, the variable reactance 950 may include the variable inductance 1500 in connection with a variable capacitance 1504 as shown in FIG. 15C. In yet another variation, the variable reactance 950 may include a fixed inductance 1506 in connection with the variable capacitance 1504. It should be recognized that the variable inductance may include multiple variable inductors and the variable capacitance may include multiple variable capacitors. Similarly, the fixed inductance may include multiple fixed inductors and the fixed capacitance may include multiple fixed capacitors. Those of skill in the art are very familiar with both controllable variable inductors and controllable variable capacitors that may be used to realize the variable inductances and variable capacitances discussed herein.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuitry described in connection with the embodiments disclosed herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC.

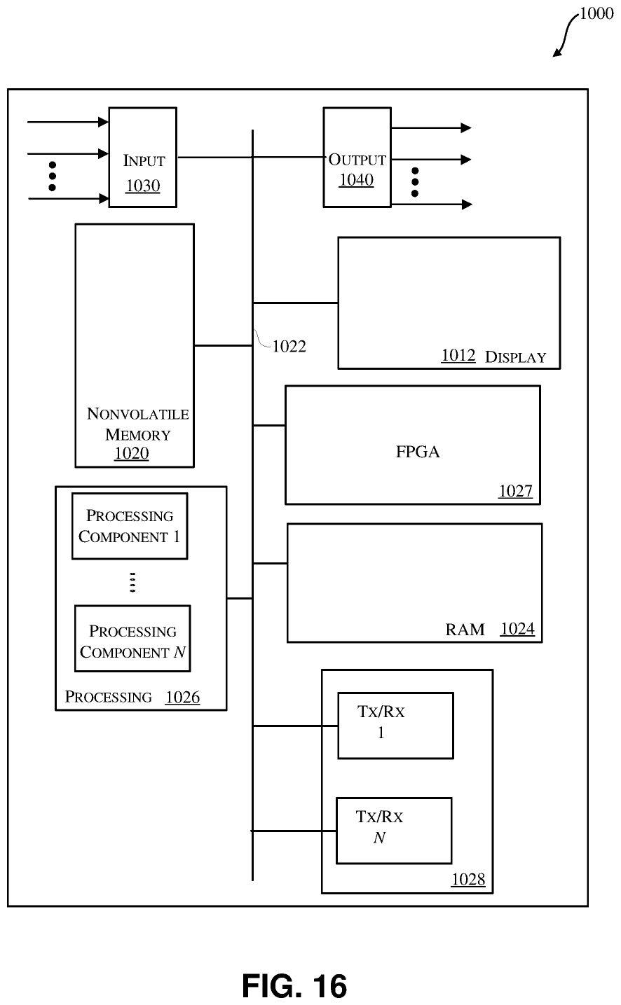

Many embodiments and methods described herein may be realized using a processor in connection with processor executable instructions and a field programmable gate array (programmed by hardware description language instructions). In some embodiments, the FPGA is used for high-speed processing and control, including switching control, measurement, pulsing, and multi-level operation while a processor is utilized for other lower-speed processing. Referring to FIG. 16 for example, shown is a block diagram 1000 depicting physical components of a controller that may be utilized to realize control aspects disclosed herein.

As shown, in this embodiment a display 1012 and nonvolatile memory 1020 are coupled to a bus 1022 that is also coupled to random access memory (“RAM”) 1024, a processing portion (which includes N processing components) 1026, a field programmable gate array (FPGA) 1027, and a transceiver component 1028 that includes N transceivers. Although the components depicted in FIG. 16 represent physical components, FIG. 16 is not intended to be a detailed hardware diagram; thus, many of the components depicted in FIG. 16 may be realized by common constructs or distributed among additional physical components. Moreover, it is contemplated that other existing and yet-to-be developed physical components and architectures may be utilized to implement the functional components described with reference to FIG. 16.

This display 1012 generally operates to provide a user interface for a user, and in several implementations, the display is realized by a touchscreen display. The display 1012 may be used, for example to depict the asymmetrical periodic voltage waveform that is applied at the output 210 of the bias supply 208. The display 1012 may also function as a touchscreen control input to enable an operator of the bias supply 208 to adjust operational parameters of the bias supply 208. For example, the voltage step, Vstep, may be adjusted, and the current compensation, Icomp, may be adjusted, and the transition circuitry 222 (e.g., the variable reactance 950) may be controlled (using a user interface of the display 1012) to achieve a desired slope for the first transition 202 and/or the second transition 204. In general, the nonvolatile memory 1020 is non-transitory memory that functions to store (e.g., persistently store) data and processor-executable code (including executable code that is associated with effectuating the methods described herein). In some embodiments for example, the nonvolatile memory 1020 includes bootloader code, operating system code, file system code, and non-transitory processor-executable code to facilitate the execution of a method for controlling the first transition 202 and/or second transition 204 during asymmetric bias waveform application.

In many implementations, the nonvolatile memory 1020 is realized by flash memory (e.g., NAND or ONENAND memory), but it is contemplated that other memory types may be utilized as well. Although it may be possible to execute the code from the nonvolatile memory 1020, the executable code in the nonvolatile memory is typically loaded into RAM 1024 and executed by one or more of the N processing components in the processing portion 1026. In general, the nonvolatile memory 1020 is non-transitory processor-readable storage medium.

The N processing components in connection with RAM 1024 generally operate to execute the processor-readable instructions stored in nonvolatile memory 1020 to enable execution of the algorithms and functions disclosed herein. It should be recognized that several algorithms are disclosed herein, but some of these algorithms are not represented in flowcharts. Processor-executable code to effectuate methods described herein may be persistently stored in nonvolatile memory 1020 and executed by the N processing components in connection with RAM 1024. As one of ordinarily skill in the art will appreciate, the processing portion 1026 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, non-transitory FPGA-configuration-instructions may be persistently stored in nonvolatile memory 1020 and accessed (e.g., during boot up) to configure a field programmable gate array (FPGA) to implement the algorithms disclosed herein.

The input component 1030 may receive power related signals (e.g., signals indicative of output current, Iₒᵤₜ, compensation current, Icomp, and voltage, Vₒᵤₜ) obtained (e.g., by current transducers, VI sensors, current transducers, and/or voltage sensors) connected to the disclosed bias supplies 208.

Although not required, in some implementations the FPGA 1027 may be used, at least in part, to realize the metrology module 236 and the FPGA 1027 may sample the power-related signals and provide the digital representations of output current, Iₒᵤₜ, and output voltage Vₒᵤₜ. In some embodiments, the processing components 1026 (in connection with processor-executable instructions stored in the nonvolatile memory 1020) are used to realize the controller 234. But the FPGA 1027 may also be used to implement these functions. In addition, the input component 1030 may receive phase information and/or a synchronization signal between bias supplies 108 and source generator 112 that are indicative of one or more aspects of an environment within a plasma processing chamber 101 and/or synchronized control between a source generator and the bias supply 208. The signals received at the input component 1030 may include, for example, synchronization signals, power control signals to the various generators and power supply units, or control signals from a user interface.

Those of ordinary skill in the art will readily appreciate that any of a variety of types of sensors such as, without limitation, directional couplers and voltage-current (VI) sensors, may be used to sample power parameters, such as voltage and current, and that the signals indicative of the power parameters may be generated in the analog domain and converted to the digital domain. In some embodiments, the signals received at the input component 1030 may also include one or more of (1) signals indicative of a total charge held in the chuck capacitor as a result of ion current flowing from the plasma to the wafer or substrate surface, (2) signals indicative of plasma characteristics derived from measuring the current flow during the capacitive discharge, (3) signals indicative of the integrated current associated with the capacitive discharge event, (4) signals indicative of the total charge released from the chuck capacitance, (5) signals indicative of the time-averaged ion current, (6) signals indicative of the resonant frequency of the AC portion of the output current, and (7) signals indicative of the time to reach full capacitive discharge, to name a few non-limiting examples.

The output component 1040 generally operates to provide one or more analog or digital signals to effectuate the gate drive signals for opening and closing of the switches. The output component 1040 may also control one or more aspects of the power supplies described herein such as the voltage sources. In addition, the output component may provide control signals to adjust variable inductors and/or variable capacitors to adjust the variable reactance 950 at the output of the bias supply 208.

The depicted transceiver component 1028 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

As used herein, the recitation of “at least one of A, B and C” or “at least one of A, B or C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A bias supply comprising:
an output node;
power circuitry configured to apply an asymmetric periodic voltage waveform at the output node wherein the asymmetric periodic voltage waveform comprises:
a first section that begins with a first negative voltage and changes during a first transition to a peak voltage before changing during a second transition to a second negative voltage; and
a second section that begins with the second negative voltage and comprises a voltage ramp between the second negative voltage and a third negative voltage; and
transition circuitry configured to adjust a slope of one, or both, of the first and second transitions.

2. The bias supply of claim 1, wherein the transition circuitry comprises a variable reactance coupled between the power circuitry and the output node.

3. The bias supply of claim 2, wherein the transition circuitry comprises a variable inductance.

4. The bias supply of claim 2, wherein the transition circuitry comprises a variable capacitance.

5. The bias supply of claim 1, wherein the transition circuitry comprises a combination of fixed and variable reactive elements.

6. The bias supply of claim 1, wherein the power circuitry comprises a switch network and at least one power supply.

7. The bias supply of claim 6, wherein the switch network comprises:
at least two switches wherein, when closed, a first of the at least two switches causes the bias supply to apply the peak voltage, and when closed, another of the at least two switches causes the bias supply to apply the second negative voltage.

8. The bias supply of claim 6, wherein the switch network comprises:
a single-switched current path, wherein the bias supply is configured to periodically close and open the single-switched current path to apply the asymmetric periodic voltage waveform at the output node.

9. The bias supply of claim 6, wherein the bias supply comprises at least two switches and at least two power supplies.

10. A method comprising:
applying a first section of an asymmetric periodic voltage waveform to a plasma processing chamber, the first section begins with a first negative voltage and changes during a first transition to a second, peak voltage before changing during a second transition to a second negative voltage;
applying a second section of the asymmetric periodic voltage waveform that begins with the second negative voltage and comprises a voltage ramp between the second negative voltage and a third negative voltage; and
adjusting a slope of one, or both, of the first and second transitions.

11. The method of claim 10, wherein adjusting the slope includes adjusting a variable reactance coupled to the plasma processing chamber.

12. The method of claim 11, wherein adjusting the variable reactance comprises adjusting a variable inductance.

13. The method of claim 11, wherein adjusting the variable reactance comprises adjusting a variable capacitance.

14. The method of claim 11, wherein adjusting the variable reactance comprises adjusting a combination of a variable capacitance and variable inductance.

15. A non-transitory processor-readable storage medium having instructions embodied thereon, the instructions are executable by a processor and/or for programming a field programmable gate array, the instructions comprising instructions for:
applying a first section of an asymmetric periodic voltage waveform to a plasma processing chamber, the first section begins with a first negative voltage and changes during a first transition to a second, peak voltage before changing during a second transition to a second negative voltage;
applying a second section of the asymmetric periodic voltage waveform that begins with the second negative voltage and comprises a voltage ramp between the second negative voltage and a third negative voltage; and
adjusting a slope of one, or both, of the first and second transitions.

16. The non-transitory processor-readable storage medium of claim 15, wherein the instructions comprise instructions for adjusting a variable reactance coupled to the plasma processing chamber.

17. The non-transitory processor-readable storage medium of claim 15, wherein the instructions comprise instructions for adjusting a variable inductance.

18. The non-transitory processor-readable storage medium of claim 15, wherein the instructions comprise instructions for adjusting a variable capacitance.

19. The non-transitory processor-readable storage medium of claim 15, wherein the instructions comprise instructions for adjusting a combination of a variable capacitance and variable inductance.
